(19) United States
(12) Patent Application Publication
(10) Pub. No.: US 2026/0150694 A1
(43) Pub. Date: May 28, 2026

(54) SEMICONDUCTOR DEVICE

(71) Applicant: Advanced Semiconductor Engineering, Inc., Kaohsiung (TW)

(72) Inventors: Chih-Hung HSU, Taoyuan (TW); Chih-Chun Hung, Taoyuan (TW); Shao-Lun Yang, Taoyuan (TW); Hsin-Wei Chang, Taoyuan (TW)

(73) Assignee: Advanced Semiconductor Engineering, Inc., Kaohsiung (TW)

(21) Appl. No.: 18/963,435

(22) Filed: Nov. 27, 2024

(51) Int. Cl. H01L 23/552; H01L 23/31; H01L 23/538; H01L 25/00; H01L 25/10

(52) U.S. Cl. CPC H10W 42/20; H10W 70/611; H10W 90/00; H10W 90/401; H10W 74/111; H10W 90/291; H10W 90/722

(57) ABSTRACT

The present disclosure relates to a semiconductor device. The semiconductor device includes a package structure, a first shielding layer, and a second shielding layer. The package structure has a first surface and a second surface opposite to the first surface, wherein the package structure has a recess recessed from the first surface. The first shielding layer is disposed on the first surface and an inner surface of the recess of the package structure. The second shielding layer is disposed in the recess and laterally connected to the first shielding layer. The first shielding layer is spaced apart from the second shielding layer.

### BACKGROUND

### 1. Technical Field

The present disclosure relates generally to a semiconductor device, and more particularly to a semiconductor device including two package structures with independent shielding layers.

### 2. Description of the Related Art

The present system-in-package (SiP) includes multiple dies (such as processors, memories, and the like) disposed side by side with a shielding layer outside the package. After the molding process, the package size is large due to the stacked dies, and thus the yield rate of the sputter process for the shielding layers may be impacted. As the technology evolves, the size is required to be shrink for applications, such as wearable devices. Therefore, an improved semiconductor device is called for.

### SUMMARY

In some embodiments, a semiconductor device includes a package structure, a first shielding layer, and a second shielding layer. The package structure has a first surface and a second surface opposite to the first surface, wherein the package structure has a recess recessed from the first surface. The first shielding layer is disposed on the first surface and an inner surface of the recess of the package structure. The second shielding layer is disposed in the recess and laterally connected to the first shielding layer. The first shielding layer is spaced apart from the second shielding layer.

In some embodiments, a semiconductor device includes a package structure, a first shielding layer, and a second shielding layer. The package structure has a first surface and a second surface opposite to the first surface. The first shielding layer is disposed on the first surface of the package structure. The second shielding layer horizontally overlaps and is spaced apart from the first shielding layer in a cross-sectional view. The second shielding layer is connected to the ground through the first shielding layer.

In some embodiments, a semiconductor device includes a first package structure and a second package structure. The first package structure includes a first electronic component and a first shielding layer covering the first electronic component. The second package structure includes a second electronic component and a second shielding layer covering the second electronic component. A wafer node of the first electronic component is different from a wafer node of the second electronic component.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1 is a cross-section of a semiconductor device, in accordance with some embodiments of the present disclosure.

FIG. 1A is an enlarged perspective view of a region “1A” in FIG. 1, in accordance with some embodiments of the present disclosure.

FIG. 2 is a cross-section of a semiconductor device, in accordance with some embodiments of the present disclosure.

FIG. 2A is an enlarged perspective view of a region “2A” in FIG. 2, in accordance with some embodiments of the present disclosure.

FIG. 3 is a cross-section of a semiconductor device, in accordance with some embodiments of the present disclosure.

FIG. 4A, FIG. 4B, FIG. 4C, FIG. 4D, FIG. 4E, and FIG. 4F illustrate one or more operations of a method for manufacturing a semiconductor device, in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

The following disclosure provides different embodiments, or examples, for implementing different features of the provided subject matter. Specific examples of components and embodiments are recited herein. These are, of course, merely examples and are not intended to be limiting. In the present disclosure, reference to the formation of a first feature over or on a second feature in the description that follows may include embodiments in which the first and second features are formed in direct contact, and may also include embodiments in which additional features may be formed between the first and second features, such that the first and second features may not be in direct contact. The present disclosure may repeat reference numerals and/or letters in the various examples. This repetition is for simplicity and clarity and does not in itself dictate a relationship between the various embodiments and/or configurations discussed.

Embodiments of the present disclosure are discussed in detail as follows. It should be appreciated, however, that the present disclosure provides many applicable concepts that can be embodied in a wide variety of specific contexts. The specific embodiments discussed are merely illustrative and do not limit the scope of the disclosure.

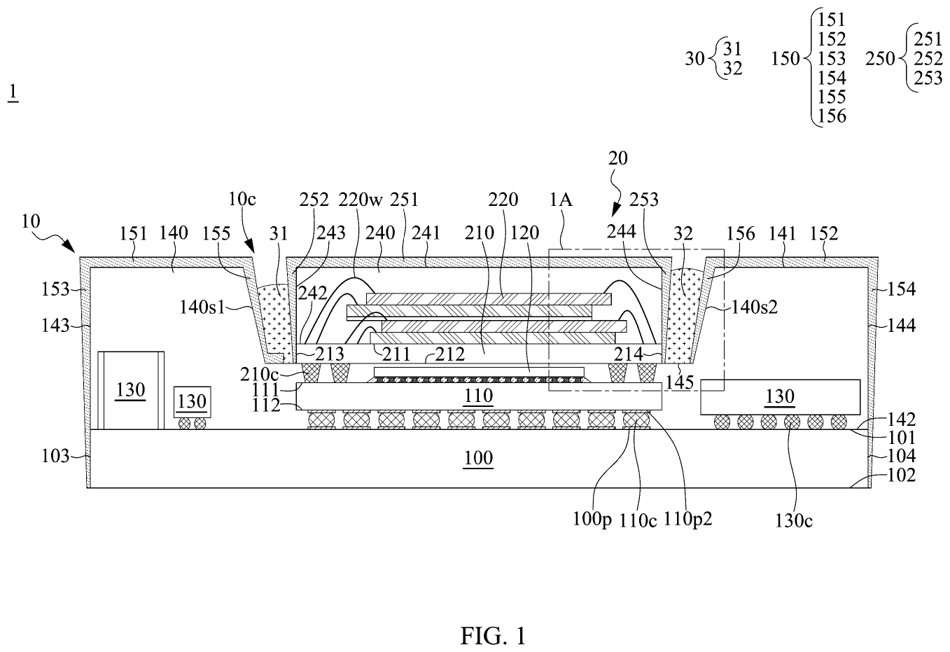

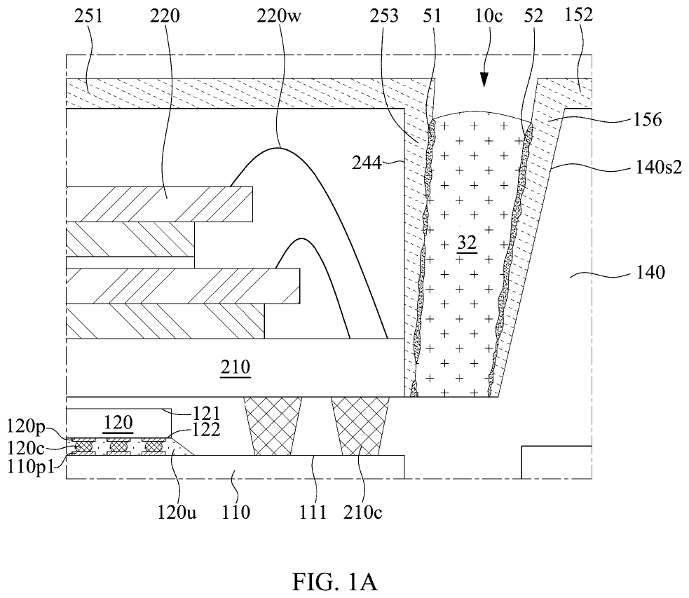

FIG. 1 is a cross-section of a semiconductor device 1, in accordance with some embodiments of the present disclosure. FIG. 1A is an enlarged perspective view of a region “1A” in FIG. 1, in accordance with some embodiments of the present disclosure. The semiconductor device 1 may include a first package structure 10, a second package structure 20, and an electrical connection element 30. In some embodiments, the first package structure 10 may include a recess 10c, and the second package structure 20 and the electrical connection element 30 may be within the recess 10c of the first package structure 10. The first package structure 10 may include a carrier 100, a substrate 110, electronic components 120 and 130, an encapsulant 140, and a shielding layer 150. The second package structure 20 may include a substrate 210, electronic components 220, an encapsulant 240, and a shielding layer 250.

The semiconductor device 1 may be or include system-on-chip (SoC), package-on-package (PoP), embedded-package-on-package (ePoP), MEMS, or the like. The semiconductor device 1 may be or include a system-in package (SiP).

Embodiments of the present disclosure discuss a semiconductor device including electronic components having different wafer nodes (or technical nodes). For example, the electronic components may be produced using a 5 nm process, a 2 nm process, or even more advanced process technology. The electronic components may be encapsulated separately according to their wafer nodes, and then be bonded together to form the semiconductor device. For example, some of the electronic components having a higher or greater wafer node (such as chips greater than 5 nm process technology) may be encapsulated to form one or more SiPs, and some other electronic components having a lower or less wafer node (such as chips less than 5 nm process technology) may be encapsulated separately. In addition, a manufacturing cost for the electronic components having a higher or greater wafer node is less than a manufacturing cost for the electronic components having a lower or less wafer node. Therefore, encapsulating the electronic components separately is further advantageous to reducing the cost. Moreover, when some of the electronic components (for example, those having a lower or less wafer node) are malfunctioned, they can be replaced independently and remain other electronic components (for example, those having a higher or greater wafer node). Accordingly, the semiconductor device can have a better flexibility.

Furthermore, the present disclosure discuss a semiconductor device including spaces or trenches between encapsulants that encapsulate electronic components with different wafer nodes. The spaces or trenches may be narrow in widths and large in depths (e.g., a relatively high aspect ratio), and when depositing a shielding metal over the encapsulants and within the gaps or trenches, the as-formed shielding layer may easily break within the spaces or trenches to form separate shielding layer over separate encapsulants. By disposing an electrical connection element (conductive materials) within the spaces or trenches, the shielding layers over different encapsulates can be electrically connected to each other and further electrically connected to the substrate. Therefore, the electromagnetic interference (EMI) shielding effect can be enhanced.

By stacking package structures one another may release the planar spaces. In addition, independently depositing shielding layers may obtain better yield rate and prevent short issue due to over disposition. In particular, the different package structures include dies having different functions (or different wafer nodes), and the shielding layers for respective package structures are connected through conductive materials/films. The shielding layers for respective package structures can provide partial shielding and enhance the EMI shielding effect of the whole semiconductor device. Moreover, encapsulating the electronic components having a higher or greater wafer node first and then integrating electronic components having a lower or less wafer node (higher manufacturing cost) into the same can improve the process yield rate because the defects in the previous process would not affect those electronic components having a lower or less wafer node. Likewise, separating different functions (or different wafer nodes) in package structures is easy to replace those malfunctioned.

The carrier 100 may include, for example, a printed circuit board, such as a paper-based copper foil laminate, a composite copper foil laminate, or a polymer-impregnated glass-fiber-based copper foil laminate. The carrier 100 may include an interconnection structure, such as a plurality of conductive traces and/or a plurality of conductive vias. In some embodiments, the carrier 100 includes a ceramic material, a metal plate, an organic substrate, or a leadframe. In some embodiments, the carrier 100 may include a two-layer substrate which includes a core layer and a conductive material and/or structure disposed on an upper surface and a bottom surface of the carrier 100. The conductive material and/or structure may include a plurality of conductive traces. The carrier 100 may include a surface 101, a surface 102 opposite to the surface 101, and lateral surfaces 103 and 104 extending between the surface 101 and the surface 102. In some embodiments, the carrier 100 includes conductive pads 100p exposed from the surface 101. In some embodiments, the carrier 100 may also include conductive pads (not shown) exposed from the surface 102. In some embodiments, the carrier 100 may include one or more ground elements (not shown) exposed from at least one of the lateral surfaces 103 and 104 and connected to the shielding layer 150.

In some embodiments, the substrate 110 may be disposed on the carrier 100. In some embodiments, the substrate 110 may carry/support the electronic component 120. The substrate 110 may include a surface 111, a surface 112 opposite to the surface 111. Referring to FIG. 1A, the substrate 110 includes conductive pads 110p1 exposed from the surface 111. Referring back to FIG. 1, the substrate 110 includes conductive pads 110p2 exposed from the surface 112. In some embodiments, the conductive pads 110p2 of the substrate 110 may face and be electrically connected to the carrier 100. The substrate 110 may include conductive elements 110c disposed between the conductive pads 110p2 of the substrate 110 and the conductive pads 100p of the carrier 100, such that the substrate 110 and the carrier 100 can be electrically connected. The conductive elements 110c may include conductive bumps, solder elements, or the like. In some embodiments, the size of the substrate 110 may be less than that of the carrier 100. For example, the thickness and width of the substrate 110 may be less than those of the carrier 100.

The substrate 110 may include, for example, a printed circuit board, such as a paper-based copper foil laminate, a composite copper foil laminate, or a polymer-impregnated glass-fiber-based copper foil laminate. The substrate 110 may include an interconnection structure, such as a plurality of conductive traces and/or a plurality of conductive vias. In some embodiments, the substrate 110 includes a ceramic material, a metal plate, an organic substrate, or a leadframe. In some embodiments, the substrate 110 may include a two-layer substrate which includes a core layer and a conductive material and/or structure disposed on an upper surface and a bottom surface of the substrate 110. The conductive material and/or structure may include a plurality of conductive traces.

The electronic component 120 may be disposed within the first package structure 10 and under the electronic component 220. The electronic component 120 may be disposed over the substrate 110. Referring to FIG. 1A, the electronic component 120 has a top surface 121 (also referred to as an upper surface), a bottom surface 122 (also referred to as a lower surface) facing the substrate 110. In some embodiments, the electronic component 120 includes conductive pads 120p exposed from or protruding from the surface 122. In some embodiments, the electronic component 120 includes conductive elements 120c facing and electrically connected to the substrate 110. The electronic component 120 is connected to the substrate 110 through the conductive elements 120c. In some embodiments, the conductive elements 120c may be connected to the conductive pads 110p1 and the conductive pads 120p. The conductive elements 120c may include conductive bumps, solder elements, or the like.

In some embodiments, the electronic component 120 include surface mount devices (SMDs). Each of the electronic component 120 may be a chip or a die including a semiconductor substrate, one or more integrated circuit devices and one or more overlying interconnection structures therein. The integrated circuit devices may include active devices such as transistors and/or passive devices such resistors, capacitors, inductors, or a combination thereof. In some embodiments, the electronic component 120 includes a processor, such as an application processor (AP). The electronic component 120 may include an active device (e.g., an application-specific integrated circuit (ASIC), or the like).

Referring to FIG. 1A, the first package structure 10 further includes a protective element 120u between the substrate 110 and the electronic component 120. In some embodiments, the protective element 120u may encapsulate the conductive elements 120c. In some embodiments, the protective element 120u may be or include an underfill. The underfill may include an epoxy resin having fillers dispersed therein, a molding compound (e.g., an epoxy molding compound or other molding compound), polyimide (PI), a phenolic compound or material, a polymer material with silicone dispersed therein, or a combination thereof.

The electronic components 130 may be disposed over the carrier 100. In some embodiments, the electronic component 130 includes conductive elements 130c facing and electrically connected to the carrier 100. In some embodiments, the electronic components 130 include surface mount devices (SMDs). Each of the electronic components 130 may be a chip or a die including a semiconductor substrate, one or more integrated circuit devices and one or more overlying interconnection structures therein. The integrated circuit devices may include active devices such as transistors and/or passive devices such resistors, capacitors, inductors, or a combination thereof. In some embodiments, the electronic component 130 includes an active device (e.g., a power management integrated circuit (PMIC), an application-specific integrated circuit (ASIC), or the like) or a passive device (e.g., a capacitor, a resistor, or the like).

The encapsulant 140 may be disposed over the surface 101 of the carrier 100. In some embodiments, the encapsulant 140 may cover or encapsulate the substrate 110 and the electronic components 120 and 130. In some embodiments, the electronic components 120 and 130 may be entirely covered by the encapsulant 140. In some embodiments, the top surface 121 of the electronic component 120 may be covered by the encapsulant 140. In some embodiments, the encapsulant 140 may define a recess 10c (or a cavity) and expose a portion of the top surface 111 of the substrate 110 to form connection elements 210c. The encapsulant 140 may have a top surface 141, a bottom surface 142 opposite to the top surface 141 and facing the carrier 100, lateral surfaces 143 and 144 connecting the top surface 141 and the bottom surface 142, a surface 145 recessed from the top surface 141, and lateral sidewalls 140s1 and 140s2 connecting the top surface 141 and the surface 145. In some embodiments, the surface 145 may be between the top surface 141 and the bottom surface 142 and substantially parallel to the top surface 141. The recess 10c may be defined by the surface 145 and the lateral sidewalls 140s1 and 140s2 of the encapsulant 140. The recess 10c may accommodate the second package structure 20. In some embodiments, the recess 10c may be recessed from the top surface 141 and taper toward the substrate 110. That is, the lateral sidewalls 140s1 and 140s2 may be inclined surfaces. The lateral sidewall 140s1 may be opposite to the lateral sidewall 140s2. In some embodiments, the lateral surface 143 of the encapsulant 140 may be aligned with the lateral surface 103 of the carrier 100, and the lateral surface 144 of the encapsulant 140 may be aligned with the lateral surface 104 of the carrier 100.

In some embodiments, the encapsulant 140 may include an epoxy resin having fillers dispersed therein, a molding compound (e.g., an epoxy molding compound or other molding compound), PI, a phenolic compound or material, a polymer material with silicone dispersed therein, or a combination thereof. The encapsulant 140 may be referred to as a selective mold. In some embodiments, the encapsulant 140 may be formed by a step mold.

The shielding layer 150 may be over the electronic components 130. In some embodiments, the shielding layer 150 covers at least the electronic components 130. The shielding layer 140 may cover the substrate 110 and the electronic component 120. In some embodiments, the shielding layer 150 may further cover the lateral surfaces 103 and 104 of the carrier 100. The shielding layer 150 may cover the encapsulant 140. For example, the shielding layer 150 may be disposed on and contact the top surface 141, the lateral surfaces 143 and 144, and the lateral sidewalls 140s1 and 140s2. In some embodiments, the ground element (not shown) of the carrier 100 may be electrically connected to the shielding layer 150.

The shielding layer 150 may be or include a conductive film, e.g., for example, aluminum (Al), copper (Cu), chromium (Cr), tin (Sn), gold (Au), silver (Ag), nickel (Ni), a mixture, an alloy, or other combination thereof. The shielding layer 150 may include multiple conductive layers. In some embodiments, the shielding layer 150 may be formed by deposition, such as the physical vapor deposition (PVD).

The shielding layer 150 may include horizontal portions 151 and 152, and wall portions 153, 154, 155, and 156. The horizontal portions 151 and 152 may cover the top surface 141 of the encapsulant 140. The wall portion 153 may cover the lateral surface 143 of the encapsulant 140 and the lateral surface 103 of the carrier 100. The wall portion 154 may cover the lateral surface 144 of the encapsulant 140 and the lateral surface 104 of the carrier 100. The wall portion 155 may cover the lateral sidewall 140s1 of the encapsulant 140 (i.e., the sidewall/inner surface of the recess 10c). In some embodiments, the wall portion 155 may extend to a corner of the recess 10c. The wall portion 156 may cover the lateral sidewall 140s2 of the encapsulant 140 (i.e., the sidewall/inner surface of the recess 10c). In some embodiments, the wall portion 156 may extend to a corner of the recess 10c and further to the surface 145 of the encapsulant 140 (i.e., the bottom surface of the recess 10c). In another embodiment, the wall portions 155 and 156 may have the same profile. In some embodiments, the horizontal portion 151 may connect the wall portions 153 and 155, and the horizontal portion 152 may connect the wall portions 154 and 156.

In some embodiments, the wall portions 153, 154, 155, and 156 may include a tapered cross-sectional profile. In some embodiments, the wall portions 153, 154, 155, and 156 may taper in a direction from the encapsulant 140 toward the carrier 100. In some embodiments, the wall portions 155 and 156 may taper toward the surface 145 of the encapsulant 140.

In some embodiments, the second package structure 20 may be disposed in the recess 10c of the first package structure 10. The second package structure 20 may be disposed between the top surface 141 and the bottom surface 142 of the encapsulant 140 of the first package structure 10.

In some embodiments, the substrate 210 may be disposed on the substrate 110. In some embodiments, the substrate 210 may carry/support the electronic components 220. The substrate 210 may include a surface 211, a surface 212 opposite to the surface 211, and lateral surfaces 213 and 214 extending from the surface 211 to the surface 212. In some embodiments, the substrate 210 may include conductive pads (not shown) exposed from the surfaces 211 and 212. In some embodiments, the substrate 210 may include conductive elements (or connectors) 210c may be disposed between the first package structure 10 and the second package structure 20. The conductive elements 210c may be disposed between the substrate 210 and the substrate 110, such that the substrate 210 and the substrate 110 can be electrically connected. The conductive elements 210c may include conductive vias, conductive bumps, solder elements, or the like. In some embodiments, the size of the substrate 210 may be substantially identical to that of the substrate 110.

The substrate 210 may include, for example, a printed circuit board, such as a paper-based copper foil laminate, a composite copper foil laminate, or a polymer-impregnated glass-fiber-based copper foil laminate. The substrate 210 may include an interconnection structure, such as a plurality of conductive traces and/or a plurality of conductive vias. In some embodiments, the substrate 210 includes a ceramic material, a metal plate, an organic substrate, or a leadframe. In some embodiments, the substrate 210 may include a two-layer substrate which includes a core layer and a conductive material and/or structure disposed on an upper surface and a bottom surface of the substrate 210. The conductive material and/or structure may include a plurality of conductive traces.

The electronic components 220 may be disposed over the substrate 210. In some embodiments, the number of the electronic components 220 may be one or more in the second package structure 20. For example, FIG. 1 shows four electronic components 220 stacked one another. In some embodiments, the electronic components 220 may be electrically connected to the substrate 210 through one or more conductive wires 220w. The conductive wires 220w may connect/bond conductive pads (not shown) on the top surface of the electronic components 220 to conductive pads (not shown) on the top surface 211 of the substrate 210.

In some embodiments, the electronic component 220 may laterally overlap the shielding layer 150 and the shielding layer 250. The electronic component 120 may be under the electronic component 220 and non-overlap the shielding layer 250 laterally. In some embodiments, the electronic component 120 may be disposed within the first package structure 10 and under the electronic component 220. The electronic component 220 may be electrically connected to the electronic component 120 through the substrates 110 and 210. In some embodiments, a wafer node (or technical node) of the electronic component 220 is less than a wafer node of the electronic components 120. In some embodiments, a gate length of transistors of the electronic component 220 is less than a gate length of transistors of the electronic components 120. In some embodiments, the electronic component 220 is or includes a storage component or memory, e.g., a dynamic random access memory (DRAM). In some embodiments, the electronic component 220 may be or include a wireless module, e.g., a radiofrequency (RF) front-end module, a Wi-Fi module, or the like.

The encapsulant 240 may be disposed over the surface 211 of the substrate 210. In some embodiments, the encapsulant 240 may cover or encapsulate the substrate 210, the electronic components 220, and the conductive wires 220w. In some embodiments, the top surface and lateral surfaces of the electronic components 220 may be covered by the encapsulant 240. The encapsulant 240 may have a top surface 241, a bottom surface 242 opposite to the top surface 241 and facing the substrate 210, and lateral surfaces 243 and 244 connecting the top surface 241 and the bottom surface 242. The top surface 241 of the encapsulant 240 may be substantially aligned with the top surface 141 of encapsulant 140 of the first package structure 10. In some embodiments, the lateral surface 243 may face the lateral sidewall 140s1 of the encapsulant 140, and the lateral surface 244 may face the lateral sidewall 140s2 of the encapsulant 140. The lateral surface 243 may be opposite to the lateral surface 244. In some embodiments, the lateral surface 243 of the encapsulant 240 may be aligned with the lateral surface 213 of the substrate 210, and the lateral surface 244 of the encapsulant 240 may be aligned with the lateral surface 214 of the substrate 210.

In some embodiments, the encapsulant 240 may include an epoxy resin having fillers dispersed therein, a molding compound (e.g., an epoxy molding compound or other molding compound), PI, a phenolic compound or material, a polymer material with silicone dispersed therein, or a combination thereof.

The shielding layer 250 may be over and cover the electronic components 220. In some embodiments, the shielding layer 250 may be disposed in the recess 10c. The shielding layer 150 may non-overlap the shielding layer 250 vertically. The shielding layer 250 may cover the encapsulant 240. For example, the shielding layer 250 may contact the top surface 241 and the lateral surfaces 243 and 144 of the encapsulant 240. The shielding layer 250 may laterally overlap and cover the substrate 210. In some embodiments, the shielding layer 250 may further cover the lateral surfaces 213 and 214 of the substrate 210. In some embodiments, the ground element (not shown) of the substrate 210 may be electrically connected to the shielding layer 250. The shielding layer 250 may horizontally/laterally overlap the shielding layer 150. In some embodiments, the shielding layer 250 may be spaced apart from the shielding layer 150. The shielding layer 250 may be connected to the ground through the shielding layer 150.

The shielding layer 250 may be or include a conductive film, e.g., for example, aluminum (Al), copper (Cu), chromium (Cr), tin (Sn), gold (Au), silver (Ag), nickel (Ni), stainless steel, a mixture, an alloy, or other combination thereof. The shielding layer 250 may include multiple conductive layers. In some embodiments, the shielding layer 250 may be formed by deposition, such as the physical vapor deposition (PVD).

The shielding layer 250 may include a horizontal portion 251 and wall portions 252 and 253. The horizontal portion 251 may cover the top surface 241 of the encapsulant 240. The wall portion 252 may cover the lateral surface 243 of the encapsulant 240 and the lateral surface 213 of the substrate 210. The wall portion 253 may cover the lateral surface 244 of the encapsulant 240 and the lateral surface 214 of the substrate 210. In some embodiments, the horizontal portion 251 may connect the wall portions 252 and 253. In some embodiments, a portion of the shielding layer 250 may be substantially aligned with a portion of the shielding layer 150. For example, the horizontal portion 251 of the shielding layer 250 may be substantially aligned with the horizontal portions 151 and 152 of the shielding layer 150.

The wall portion 252 may face the lateral sidewall 140s1 of the encapsulant 140 (i.e., the sidewall/inner surface of the recess 10c). That is, the wall portion 252 of the shielding layer 250 may face and be spaced apart from the wall portion 155 of the shielding layer 150. The wall portion 253 may face the lateral sidewall 140s2 of the encapsulant 140 (i.e., the sidewall/inner surface of the recess 10c). That is, the wall portion 253 of the shielding layer 250 may face and be spaced apart from the wall portion 156 of the shielding layer 150. In some embodiments, the shielding layer 150 within the recess 10c (i.e., the wall portions 155 and 156) may extend in a direction non-parallel to the shielding layer 250. The wall portion 155 of the shielding layer 150 is non-parallel to the wall portion 252 of the shielding layer 250. The wall portion 156 of the shielding layer 150 is non-parallel to the wall portion 253 of the shielding layer 250.

In some embodiments, the wall portions 252 and 253 may include a tapered cross-sectional profile. In some embodiments, the wall portions 252 and 253 may taper in a direction from the encapsulant 240 toward the substrate 110. In some embodiments, a roughness of the shielding layer 150 may be greater than a roughness of the shielding layer 250. The ends of the shielding layer 150 may have a greater roughness due to the removing process (such as the laser ablation) performed on the shielding layer 150 for exposing the surface 145 of the encapsulant 140. For example, the end of the wall portions 155 and 156 of the shielding layer 150 cut by the laser ablation may have a greater roughness.

The electrical connection element 30 may be disposed in the recess 10c of the first package structure 10. In some embodiments, the electrical connection element 30 may laterally overlap the electronic component 220. The electrical connection element 30 may be disposed between the shielding layer 150 and the shielding layer 250. In some embodiments, the electrical connection element 30 electrically connects/attaches the shielding layer 150 to the shielding layer 250. In some embodiments, the electrical connection element 30 contacts the shielding layer 150 and the shielding layer 250. In some embodiments, the electrical connection element 30 overlaps (or horizontally/laterally overlaps) the shielding layer 150 and the shielding layer 250 in a direction substantially parallel to the surface 101 of the carrier 100. That is, the shielding layer 250 may be laterally connected to the shielding layer 150 through the electrical connection element 30. The electrical connection element 30 may be disposed on the surface 145 of the encapsulant 140. In some embodiments, the electrical connection element 30 may be free from contacting the conductive elements 210c. The electrical connection element 30 may be separated from the substrate 210.

An upper surface of the electrical connection element 30 may be lower than an upper surface of at least one of the shielding layers 150 and 250 with respect to the top surface 101 of the carrier 100. In some embodiments, the electrical connection element 30 includes a conductive material, such as a solder material, a conductive paste, a conductive layer, a conductive film, or the like.

The electrical connection element 30 may electrically connect the shielding layer 150 to the shielding layer 250 and has an upper surface lower than upper surfaces of the shielding layers 150 and 250, and thus the electrical connection element 30 does not protrude beyond the upper surfaces of the shielding layers 150 and 250. Therefore, the electromagnetic interference (EMI) shielding effect can be enhanced without undesirably increasing the thickness of the semiconductor device 1. In addition, independently depositing the shielding layers on small area can obtain better yield rate. Therefore, integrating package structures with respective shielding layers, the semiconductor device 1 can have higher device density and better EMI shielding effect.

The electrical connection element 30 may include a portion 31 and a portion 32 at the opposite side of the second package structure 20. The portion 31 may be between and contact the wall portion 155 and the wall portion 252. The portion 32 may be between and contact the wall portion 156 and the wall portion 253. In some embodiments, an elevation of an upper surface of the portion 31 may be different from an elevation of an upper surface of the portion 32. In some embodiments, a thickness of the portion 31 may be different from that of the portion 32. For example, the thickness of the portion 31 may be less than that of the portion 32.

In some embodiments, at least one of the upper surfaces of the portions 31 and 32 of the electrical connection element 30 includes a non-planar surface. In some embodiments, at least one of the upper surfaces of the portions 31 and 32 of the electrical connection element 30 includes a curved surface. For example, the upper surface of the portions 31 and 32 of the electrical connection element 30 may be convex away from the carrier 100. In another embodiment, the upper surface of the portions 31 and 32 of the electrical connection element 30 may be concave toward an inner portion thereof (not shown).

In some embodiments, metal layers 51 and 52 may exist between the electrical connection element 30 and the shielding layers 150 and 250. Referring to FIG. 1A, the metal layer 51 may have an irregular boundary and be formed between the portion 32 of the electrical connection element 30 and the wall portion 253 of the shielding layer 250. In some embodiments, a part of an interface of the portion 32 of the electrical connection element 30 and the wall portion 253 of the shielding layer 250 may be free from the metal layer 51. In some embodiments, the metal layer 52 may have an irregular boundary and be formed between the portion 32 of the electrical connection element 30 and the wall portion 156 of the shielding layer 150. In some embodiments, a part of an interface of the portion 32 of the electrical connection element 30 and the wall portion 156 of the shielding layer 150 may be free from the metal layer 52. The metal layers 51 and 52 may be the intermetallic compound (IMC). In some embodiments, the thinner thickness of the metal layers 51 and 52 may have a better electrical conductivity. In other embodiments, the semiconductor device 1 may have no metal layers 51 and 52.

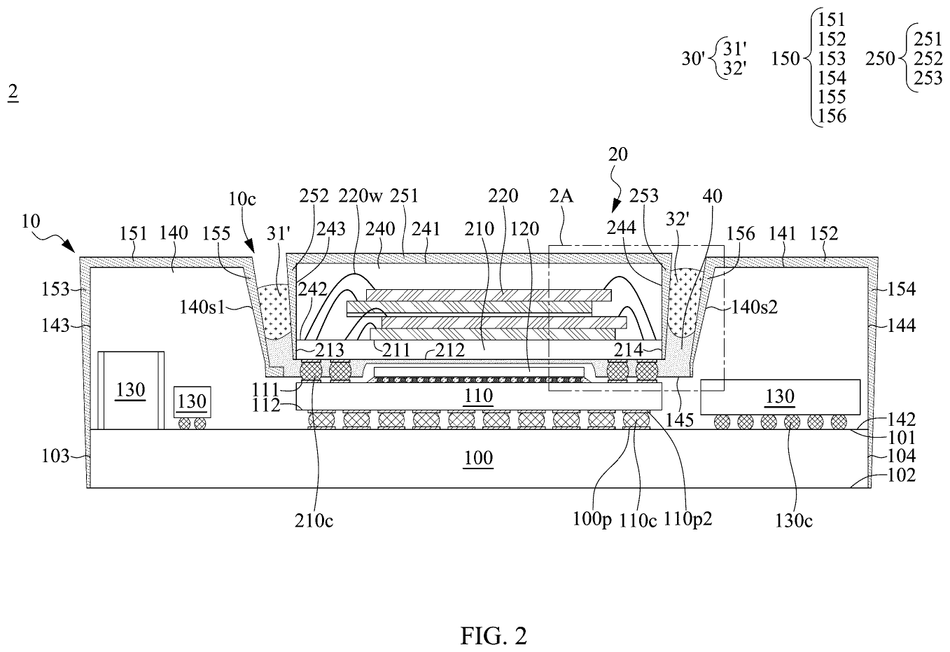

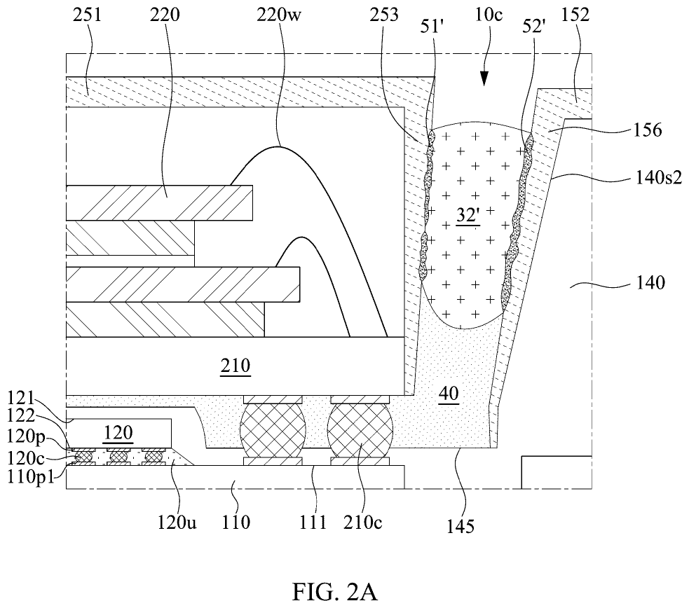

FIG. 2 is a cross-section of a semiconductor device 2, in accordance with some embodiments of the present disclosure. FIG. 2A is an enlarged perspective view of a region “2A” in FIG. 2, in accordance with some embodiments of the present disclosure. The semiconductor device 2 is similar to the semiconductor device 1 in FIG. 1 and FIG. 1A, and the differences therebetween are described as follows.

Referring to FIG. 2, the semiconductor device 2 further includes a protective element 40 disposed within the recess 10c and between the first package structure 10 and the second package structure 20. In some embodiments, the protective element 40 may encapsulate the conductive elements 210c connecting the second package structure 20 to the first package structure 10. In some embodiments, the protective element 40 may be disposed between the conductive elements 210c and the electrical connection element 30′. In some embodiments, the conductive elements 210c may be separated from the electrical connection element 30′ by the protective element 40. The protective element 40 may be below the electrical connection element 30′. In some embodiments, the electrical connection element 30′ may be similar to the electrical connection element 30 differing in arrangements/shapes.

The protective element 40 may be filled between the encapsulant 140 and the substrate 210. That is, the protective element 40 may be vertically overlap the substrate 210. The protective element 40 may cover the shielding layers 150 and 250. In some embodiments, the substrate 210 may be separated from the electrical connection element 30′ by the protective element 40. The protective element 40 may laterally overlap the substrate 210. The protective element 40 may laterally overlap the electronic component 120.

In some embodiments, the protective element 40 may be or include an underfill. The underfill may include an epoxy resin having fillers dispersed therein, a molding compound (e.g., an epoxy molding compound or other molding compound), polyimide (PI), a phenolic compound or material, a polymer material with silicone dispersed therein, or a combination thereof.

Referring to FIG. 2A, the shielding layer 150 may be partially below the second shielding layer 250. The shielding layer 150 within the recess 10c may be partially exposed by the electrical connection element 30′, and the shielding layer 250 within the recess 10c may be partially exposed by the electrical connection element 30′. In some embodiments, the shielding layers 150 and 250 exposed by the electrical connection element 30′ may be covered by the protective element 40. The electrical connection element 30′ may be far from the surface 145 of the encapsulant 140 than the shielding layer 150 is. The electrical connection element 30′ may be far from the surface 145 of the encapsulant 140 than the shielding layer 250 is.

In some embodiments, at least one of the lower surfaces of the portions 31′ and 32′ of the electrical connection element 30′ includes a non-planar surface. In some embodiments, at least one of the lower surfaces of the portions 31′ and 32′ of the electrical connection element 30′ includes a curved surface. For example, the lower surface of the portions 31′ and 32′ of the electrical connection element 30′ may be convex toward the carrier 100.

In some embodiments, metal layers 51′ and 52′ may exist between the electrical connection element 30′ and the shielding layers 150 and 250. Referring to FIG. 2A, the metal layer 51′ may have an irregular boundary and be formed between the portion 32′ of the electrical connection element 30′ and the wall portion 253 of the shielding layer 250. In some embodiments, a part of an interface of the portion 32′ of the electrical connection element 30′ and the wall portion 253 of the shielding layer 250 may be free from the metal layer 51′. In some embodiments, the metal layer 52′ may have an irregular boundary and be formed between the portion 32′ of the electrical connection element 30′ and the wall portion 156 of the shielding layer 150. In some embodiments, a part of an interface of the portion 32′ of the electrical connection element 30′ and the wall portion 156 of the shielding layer 150 may be free from the metal layer 52′. The metal layers 51′ and 52′ may be the intermetallic compound (IMC). In some embodiments, the thinner thickness of the metal layers 51′ and 52′ may result in improved electrical conductivity. In other embodiments, the semiconductor device 2 may have no metal layers 51′ and 52′.

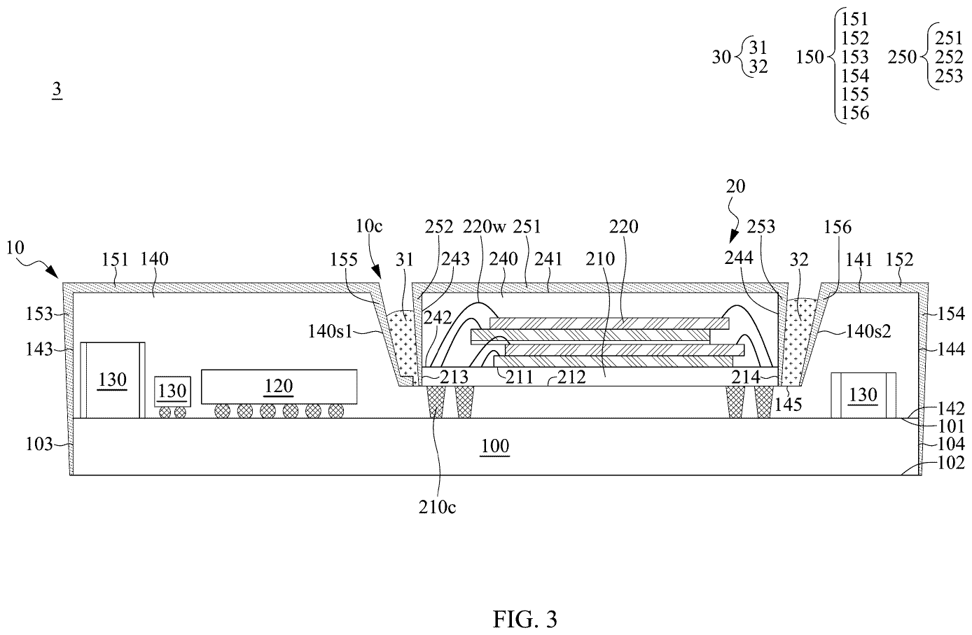

FIG. 3 is a cross-section of a semiconductor device 3, in accordance with some embodiments of the present disclosure. The semiconductor device 3 is similar to the semiconductor device 1 in FIG. 1 and FIG. 1A, and the differences therebetween are described as follows.

Referring to FIG. 3, the electronic component 120 and the second package structure 20 may be disposed side by side. That is, the second package structure 20 may be directly connected to the carrier 100 through the conductive elements 210c. In some embodiments, the electronic component 120 may laterally overlap the conductive element 210c. The electronic component 120 may be connected to the electronic components 220 in the second package structure 20 through the carrier 100.

In some embodiments, a wafer node (or technical node) of the electronic component 220 is less than a wafer node of the electronic components 120. In some embodiments, the manufacturing cost for the electronic component 220 is higher than the manufacturing cost for the electronic components 120. In some embodiments, the electronic component 220 is or includes a storage component, e.g., a dynamic random access memory (DRAM). In some embodiments, the electronic component 220 may be or include a wireless module, e.g., a radiofrequency (RF) front-end module, a Wi-Fi module, or the like. When the electronic components 220 in the second package structure 20 (those having a lower or less wafer node) are malfunctioned, they can be replaced but remain other electronic components 120 and 130 in the first package structure 10 (those having a higher or greater wafer node). Accordingly, the semiconductor device 3 can have a better flexibility and the thickness thereof can be decreased.

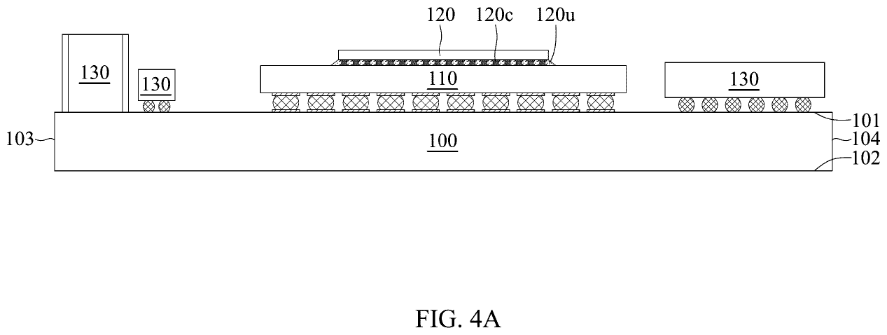

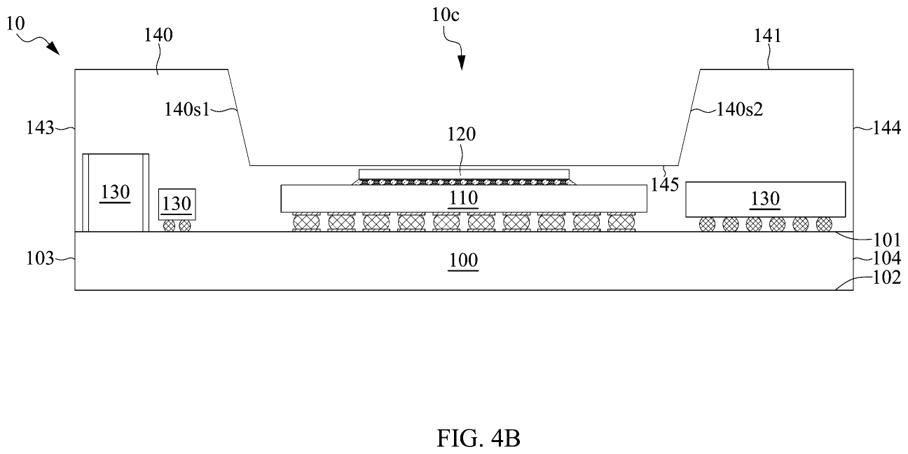

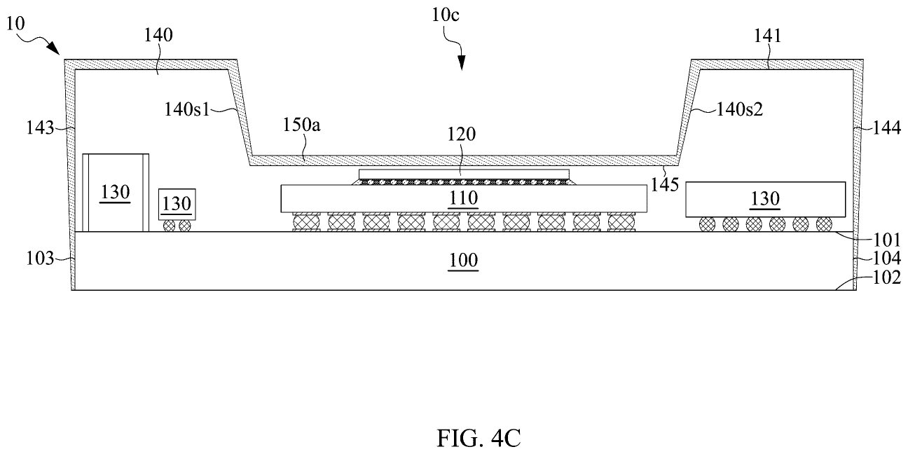

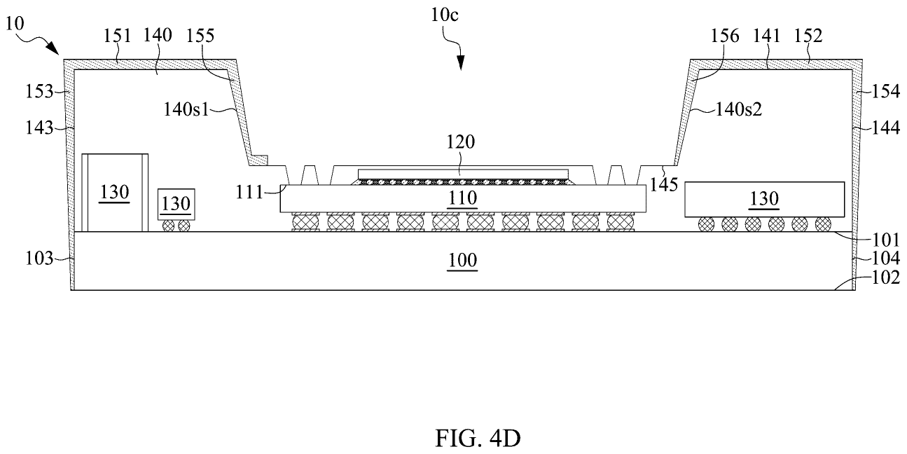

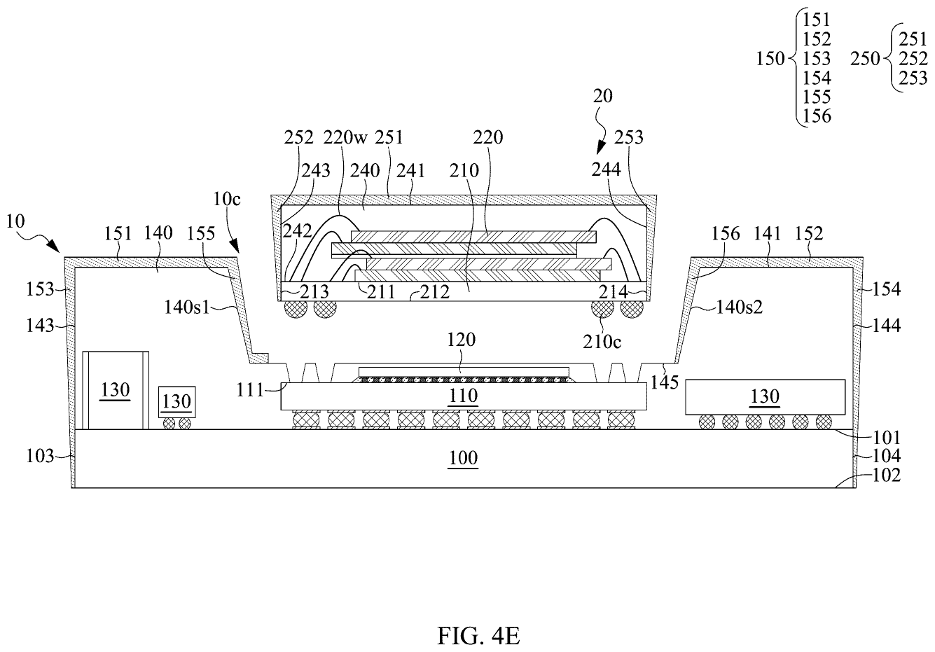

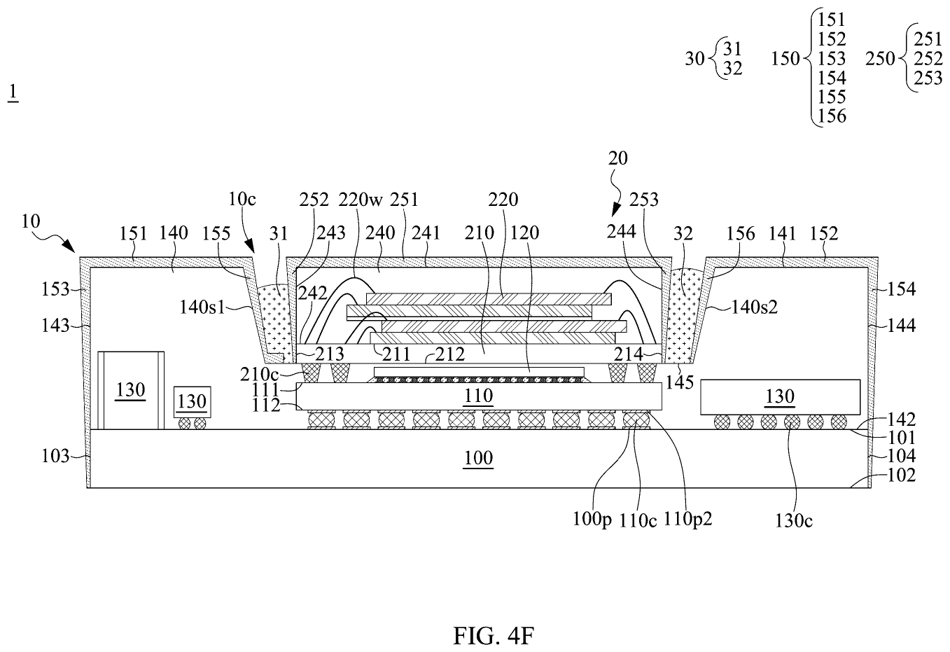

FIG. 4A, FIG. 4B, FIG. 4C, FIG. 4D, FIG. 4E, and FIG. 4F illustrate one or more operations of a method for manufacturing a semiconductor device 1, in accordance with some embodiments of the present disclosure.

Referring to FIG. 4A, a carrier 100 is provided with a substrate 110 and one or more electronic components 130 disposed thereon through conductive elements 110c and 130c. In some embodiments, an electronic component 120 may be disposed on the substrate 110 through conductive elements 120c with a protective element 120u encapsulating the same.

Referring to FIG. 4B, an encapsulant 140 may be formed to encapsulate the substrate 110 and electronic components 120 and 130. In some embodiments, a recess 10c may be formed in the encapsulant 140. The recess 10c may be defined by the surface 145 and the lateral sidewalls 140s1 and 140s2 of the encapsulant 140. In some embodiments, the encapsulant 140 may be formed by a step molding process.

Referring to FIG. 4C, a shielding layer 150a may be formed to cover the encapsulant 140. The shielding layer 150a may be disposed within the recess 10c. For example, the shielding layer 150a may be disposed on the surface 145 and the lateral sidewalls 140s1 and 140s2. The shielding layer 150a may cover the top surface 141 and the lateral surfaces 143 and 144. In some embodiments, the shielding layer 150a also covers the lateral surfaces 103 and 104 of the carrier 100. The shielding layer 150a may be formed by a physical vapor deposition (PVD) operation.

Referring to FIG. 4D, a removing process may be performed on a part of the shielding layer 150a, such that the bottom surface of the recess 10c (i.e., the surface 145 of the encapsulant 140) may be exposed. In some embodiments, the shielding layer 150a may be removed by a laser ablation or other suitable process to form the shielding layer 150, including the horizontal portions 151 and 152 and wall portions 153, 154, 155, and 156. In some embodiments, a portion of the shielding layer 150a may remain on the surface 145 of the encapsulant 140. For example, the shielding layer 150a may partially remain at the corner of the recess 10c and partially cover the surface 145. In some embodiments, a roughness of the shielding layer 150 is greater than a roughness of the shielding layer 250. The ends of the shielding layer 150 may have a greater roughness due to the laser ablation. For example, the end of the wall portions 155 and 156 of the shielding layer 150 cut by the laser ablation may have a greater roughness. In some embodiments, a part of the encapsulant 140 may be remove to form one or more openings exposing the top surface 111 of the substrate 110, wherein the openings may taper toward the substrate 110.

Referring to FIG. 4E, the second package structure 20 may be disposed in the recess 10c and mounted on the first package structure 10. In some embodiments, the second package structure 20 may be connected the top surface 111 of the substrate 110 through the conductive elements 210c.

Referring to FIG. 4F, an electrical connection element 30 may be disposed in the recess 10c and between the shielding layers 150 and 250. In some embodiments, the electrical connection element 30 may be formed by a reflow operation or a cure operation. The electrical connection element 30 may connect the shielding layer 250 to the shielding layer 150 to the ground. As such, the semiconductor device 1 illustrated in FIGS. 1 and 1A may be formed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A semiconductor device, comprising:
a package structure having a first surface and a second surface opposite to the first surface, wherein the package structure has a recess recessed from the first surface;
a first shielding layer disposed on the first surface and an inner surface of the recess of the package structure; and
a second shielding layer disposed in the recess and laterally connected to the first shielding layer,
wherein the first shielding layer is spaced apart from the second shielding layer.

2. The semiconductor device of claim 1, further comprising:
a conductive material disposed between the first shielding layer and the second shielding layer; and
an intermetallic compound (IMC) layer between the conductive material and the first shielding layer or the second shielding layer.

3. The semiconductor device of claim 2, wherein the recess of the package structure has a third surface recessed from the first surface, wherein the conductive material is far from the third surface of the recess of the package structure than the first shielding layer is.

4. The semiconductor device of claim 2, wherein the first shielding layer within the recess of the package structure is partially exposed by the conductive material, and wherein the second shielding layer within the recess of the package structure is partially exposed by the conductive material.

5. The semiconductor device of claim 1, further comprising a first electronic component disposed in the recess of the package structure and covered by the second shielding layer.

6. The semiconductor device of claim 5, further comprising a second electronic component within the package structure and under the first electronic component, wherein the second electronic component is electrically connected to the first electronic component.

7. A semiconductor device, comprising:
a package structure having a first surface and a second surface opposite to the first surface;
a first shielding layer disposed on the first surface of the package structure; and
a second shielding layer horizontally overlapping and spaced apart from the first shielding layer in a cross-sectional view, wherein the second shielding layer is connected to the ground through the first shielding layer.

8. The semiconductor device of claim 7, further comprising an electrical connection element disposed between the first shielding layer and the second shielding layer.

9. The semiconductor device of claim 8, wherein the electrical connection element laterally attaches the first shielding layer to the second shielding layer in the cross-sectional view.

10. The semiconductor device of claim 7, wherein a roughness of the first shielding layer is greater than a roughness of the second shielding layer.

11. The semiconductor device of claim 7, wherein a portion of the first shielding layer is substantially aligned with a portion of the second shielding layer.

12. The semiconductor device of claim 7, wherein the first shielding layer non-overlaps the second shielding layer vertically in a cross-sectional view.

13. A semiconductor device, comprising:
a first package structure including a first electronic component and a first shielding layer covering the first electronic component; and
a second package structure including a second electronic component and a second shielding layer covering the second electronic component,
wherein a wafer node of the first electronic component is different from a wafer node of the second electronic component.

14. The semiconductor device of claim 13, wherein the first package structure has a first surface and a second surface opposite to the first surface, wherein the second package structure is disposed between the first surface and the second surface.

15. The semiconductor device of claim 14, wherein the first package structure has a recess for accommodating the second package structure, and wherein the recess is recessed from the first surface and tapers toward the second surface.

16. The semiconductor device of claim 13, wherein the wafer node of the first electronic component is less than the wafer node of the second electronic component.

17. The semiconductor device of claim 13, further comprising:
a conductive material connecting the first shielding layer to the second shielding layer; and
a connector disposed between the first package structure and the second package structure.

18. The semiconductor device of claim 17, further comprising an underfill between the first package structure and the second package structure, wherein the underfill separates the connector from the conductive material.

19. The semiconductor device of claim 13, further comprising a conductive material connecting the first shielding layer to the second shielding layer and laterally overlapping the second electronic component in a cross-sectional view.

20. The semiconductor device of claim 19, wherein the second package structure includes a second substrate carrying the second electronic component, wherein the second substrate is separated from the conductive material by the underfill.
